(19) United States
(12) Patent Application Publication
(10) Pub. No.: US 2014/0106258 A1
(43) Pub. Date: Apr. 17, 2014

(54) Truncated Ditetragonal Gold Prisms

(71) Applicant: Brookhaven Science Associates, LLC, Upton, NY (US)

(72) Inventors: Fang Lu, Middle Island, NY (US); Oleg Gang, Setauket, NY (US); Yugang Zhang, Middle Island, NY (US); Yu Zhang, Center Moriches, NY (US); Jia X. Wang, East Setauket, NY (US)

(73) Assignee: Brookhaven Science Associates, LLC, Upton, NY (US)

(21) Appl. No.: 14/054,188

(22) Filed: Oct. 15, 2013

Related U.S. Application Data
(60) Provisional application No. 61/713,879, filed on Oct. 15, 2012.

(51) Int. Cl. C30B 29/66; C30B 7/14; C30B 29/02; H01M 4/86

(52) U.S. Cl. CPC C30B 29/66; H01M 4/8657; C30B 7/14; C30B 29/02; B82Y 40/00
USPC 429/524; 502/344; 502/439; 429/532; 429/525; 429/526; 428/402; 117/68; 977/777

(57) ABSTRACT

Truncated ditetragonal gold prisms (Au TDPs) are synthesized by adding a dilute solution of gold seeds to a growth solution, and allowing the growth to proceed to completion. The Au TDPs exhibit the face-centered cubic crystal structure and are bounded by 12 high-index {310} facets. The Au TDPs may be used as heterogeneous catalysts as prepared, or may be used as substrates for subsequent deposition of an atomically thin layer of a platinum group metal catalyst. When the Au TDPs are used as substrates, the atomically thin layer of metal reproduces the high-index facets of the Au TDPs.

### CROSS-REFERENCE TO A RELATED APPLICATION

This application claims the benefit under 35 U.S.C. 119(e) of U.S. Provisional Application No. 61/713,879 filed on Oct. 15, 2012, the content of which is incorporated herein in its entirety.

### STATEMENT OF GOVERNMENT LICENSE RIGHTS

The present invention was made with government support under contract number DE-AC02-98CH10886 awarded by the U.S. Department of Energy. The United States government has certain rights in this invention.

### FIELD OF THE INVENTION

The present invention relates to metal nanostructures useful in catalysis. More particularly, this invention relates to the design, synthesis and application of novel high-index gold nanoparticles, specifically truncated ditetragonal prisms, that act as activators of supported catalytic materials.

### BACKGROUND

Surfaces and surface structure determine many of the physical and chemical properties of crystalline matter. Substantial recent research regarding nanoparticle (NP) synthesis has been devoted to controlling the shape of nanoscale objects. Such particles possess well-defined crystallographic facets, which allows for tuning of their surface-dependent properties. In particular, high-index-faceted metal nanoparticles are of great interest due to their potential use in plasmonic and catalytic applications.

The synthesis of metallic NPs through control of the growth of low-index facets such as {111} and {100} results in NPs with well-defined shapes, such as cubes, octahedra, and rods. (See, e.g., Tao, et al. Nature Nanotechnology 2007, 2, 435; Niu, et al. J. Am. Chem. Soc. 2009, 131, 697; Millstone, et al. Nano Lett. 2008, 8, 2526; and Personick, et al. J. Am. Chem. Soc. 2011, 133, 6170; each of which is incorporated in this disclosure by reference in its entirety.)

In contrast, expression of high-index facets on metallic NPs can permit formation of more complex shapes with higher surface reaction activity. Indeed, a large density of atomic steps and terraces on high-index facets is greatly desirable for breaking and forming chemical bonds during catalytic reactions. However, the low stability of these surfaces leads to their disappearance during a crystal growth. (Tian, et al. Science 2007, 316, 732; incorporated in this disclosure by reference in its entirety). For example, only limited systems of gold (Au) NPs with high-index facets, such as trisoctahedra (TOH) (Ma, et al. Angew. Chem., Int. Ed. 2008, 47, 8901; Zhang, et al. Chem. Commun. 2011, 47, 10353; each of which is incorporated in this disclosure by reference in its entirety), tetrahexahedra (THH) (Ming, et al. J. Am. Chem. Soc. 2009, 131, 16350; incorporated in this disclosure by reference in its entirety), and concave cubes (Zhang, et al. J. Am. Chem. Soc. 2010, 132, 14012; Huang, et al. J. Am. Chem. Soc. 2011, 133, 4718; each of which is incorporated in this disclosure by reference in its entirety), have been prepared. To shape and stabilize nanofacets, the organic molecules or polymers are used as surface capping agents, which is accompanied by the growth of high-index-faceted NPs. These surfactants usually possess a strong affinity to the confined NP surfaces, and thereby passivate the desired surface activity from high-index nanofacets in the form of residue (Trong, et al. J. Phys. Chem. C. 2011, 115, 3638; incorporated in this disclosure by reference in its entirety). It is believed that the high sensitivity of surface reactions to the purity of nanofacets is responsible for lack of electrochemical activity observed in prior studies of high-index-faceted NPs (e.g. Ma, 2008; Zhang, 2011).

Thus, there is a continuing need to develop new methods to synthesize high-index nanoparticles, especially of gold, that can produce pure nanofacets for use in plasmonic and catalytic applications.

### SUMMARY

In view of the described problems, needs, and goals, a plurality of nanoscale gold (Au) truncated ditetragonal nanoprisms (TDPs) with high-index facets are disclosed. In an embodiment, the Au TDPs are bounded by 12 high-index {310} facets and show shape monodispersity. These nanoscale gold TDPs can be used in plasmonic and catalytic applications. In one exemplary embodiment, the Au TDP nanoparticles (NPs) are used as a stable facet-specific support for catalytically active metals, such as platinum (Pt). In such embodiments, Pt exhibits a high electrochemical catalytic activity due to high-index-facet features of the Au TDPs. In contrast to core/shell synthesis methods of prior art where surface features are typically not replicated during the shell formation, the atomic layer of the catalytically active metals that coats Au TDPs reproduces the surface features of the Au TDP (i.e., high-index facets).

Also disclosed is a facile seed-mediated method for synthesizing gold nanoparticles with high-index facets by using cetylpyridinium chloride (CPC) as an adsorbate surfactant. The method provides a high-yield (>95%) synthesis of uniform Au TDP NPs (e.g. ˜45 nm in size), which are bounded by 12 high-index {310} facets. In contrast to methods of the prior art, the disclosed method allows for easy surfactant removal based on a distinct electrochemical feature of Au nanofacets. The seed-mediated method relies on appropriately combining metallic ions, halide ions, and surfactant adsorbates with the gold seeds and the gold ion source. In one exemplary embodiment, the seed-mediated method generally involves (1) injecting Au seeds into a growth solution under stirring containing a chloroauric acid (HAuCl₄), silver nitrate (AgNO₃), hydrochloric acid (HCl), ascorbic acid (AA), and cetylpyridinium chloride (CPC), and (2) keeping the solution undisturbed for 2 to 48 hours to allow the growth process.

These and other characteristics of the nanoscale gold truncated ditetragonal nanoprisms with high-index facets and methods of synthesis of such crystalline matter will become more apparent from the following description and illustrative embodiments, which are described in detail with reference to the accompanying drawings. Similar elements in each figure are designated by like reference numbers and, hence, subsequent detailed descriptions of such elements have been omitted for brevity.

### BRIEF DESCRIPTION OF THE DRAWINGS

FIG. 1A is a plot showing a X-ray powder diffraction (XRD) pattern taken from synthesized gold truncated ditetragonal nanoprisms (Au TDPs) having a longest edge length of about 45 nm.

FIG. 1B is a scanning electron microscopy (SEM) image of Au TDP nanoparticles with edge length of 72±8 nm synthesized by adding the equivalent of 0.2 μL of the non-diluted seed solution.

FIG. 1C is a large-area SEM image of synthesized Au TDP nanoparticles having an edge length of 45±4 nm.

FIG. 1D is a high-magnification SEM image of Au TDP nanoparticles illustrated in FIG. 1C.

FIG. 1E is a high-magnification SEM image of Au TDP nanoparticles from FIG. 1C stressing typical TDP profiles in random orientations.

FIG. 2 is a model of an ideal TDP bound by {310} facets with major axes and directions of view marked.

FIGS. 3A-3C illustrate the projections along three orthogonal directions indicated by the arrows in FIG. 2, respectively.

FIGS. 4A-4C are high-magnification SEM images of individual nanoparticles corresponding to the TDP projections in FIGS. 3A-3C, respectively.

FIG. 5A illustrates a TEM image (left), a schematic model (middle), and a selected area electron diffraction (SAED) pattern (right) of a single Au TDP oriented along the [001] axis.

FIG. 5B illustrates a TEM image (left), a schematic model (middle), and a selected area electron diffraction (SAED) pattern (right) of a single Au TDP oriented along the [013] axis.

FIG. 5C illustrates a TEM image (left), a schematic model (middle), and a selected area electron diffraction (SAED) pattern (right) of a single Au TDP oriented along the [010] axis.

FIG. 5D illustrates a TEM image (left), a schematic model (middle), and a selected area electron diffraction (SAED) pattern (right) of a single Au TDP oriented along the [031] axis.

FIG. 6 is an annular dark field STEM image of Au NPs bounded by {310} facets with shapes similar to TDP.

FIGS. 7A-7C are crystal models proposed for the Au NPs bounded by 12 {310} facets with shape similar to TDP, corresponding to the NPs detected and shown in FIG. 6.

FIG. 8 is a plot showing UV-VIS absorbance spectra of the synthesized Au TDP NPs (solid line), the octahedral (OC) Au NPs from the control experiment with adding HCl but without AgNO₃ (dashed line), and the rhombic dodecahedral (RD) Au NPs obtained from the control experiment with adding AgNO₃ but without HCl (dotted line).

FIG. 9A is a TEM image of a [010]-oriented Au TDP NP shown at 20 nm scale.

FIG. 9B is a high-resolution TEM image of the lower right-hand corner region of the Au TDP NP TEM image illustrated in FIG. 9A.

FIG. 10 is a SEM image of an ordered assembly of {111}-facet-bounded octahedral NPs (OC) prepared without adding HCl or AgNO₃.

FIG. 11A is a SEM image of an ordered assembly of octahedral NPs (OC) prepared with HCl but without AgNO₃.

FIG. 11B is a diffraction pattern of an octahedral Au NPs (OC) prepared with HCl but without AgNO₃.

FIGS. 11C-11D is a TEM image (in FIG. 11C) of an octahedral NP prepared with HCl but without AgNO₃ and its corresponding model (in FIG. 11D).

FIG. 12 is a SEM image of an ordered assembly of {110}-facet-bounded rhombic dodecahedral NPs (RD) prepared by adding AgNO₃ without HCl. The inset shows an image of a single NP at 50 nm scale with the facet outline.

FIGS. 13A-13C are TEM images (on the left) of the {110}-facet-bounded rhombic dodecahedral NPs (RD) in various orientations at 100 nm scale and their corresponding models (on the right).

FIG. 14A is a diffraction pattern of the {110}-facet-bounded rhombic dodecahedral NPs (RD) prepared with AgNO₃ but without HCl.

FIGS. 14B-14C is a TEM image (in FIG. 14B) of the rhombic dodecahedral NP and its corresponding model (in FIG. 14C).

FIG. 15 is a schematic illustration showing the mechanism of formation of Au NPs (OC, RD, and TDP) bound by different index facets ({111}, {110}, and {310} respectively) and the corresponding atomic models of these facets viewed along zone axis [111], [100] and [100], respectively.

FIG. 16A is a plot that shows cyclic voltammetry (CV) curves for Au TDPs (solid line) and Au TDPs coated with an atomically thin layer of Pt (dotted line).

FIG. 16B is a plot that shows CV curves for Au TDPs (solid Au (TDP)-Pt(ML) and dotted lines Au (TDP)-Pt(ML) Current amplified×10) and Pt spheres (dashed line).

FIG. 16C is a plot that shows polarization curves in hydrogen-saturated 0.1 M H₂SO₄ solutions taken at 5 mV s⁻¹ and a 2500 rpm rotation rate for Au TDPs (solid line) and Pt spheres (dotted line).

FIG. 17A is a SEM image of a Au cube (CB) oriented along the [001] axis.

FIG. 17B is a schematic model of the Au cube shown in FIG. 17A.

FIG. 17C is a TEM image of a Au cube (CB) oriented along the [001] axis.

FIG. 17D is a selected area electron diffraction (SAED) pattern of a Au cube oriented along the [001] axis.

FIG. 18 is a plot showing oxygen reduction polarization curves in oxygen-saturated 0.1 M NaOH solutions taken at 50 mV s⁻¹ and a 1600 rpm rotation rate for Au TDP, CB, and OC nanocrystals.

FIG. 19A is a plot showing the oxygen reduction measured on a rotating disk-ring electrode in oxygen-saturated 0.1 M NaOH solutions for Au TDPs (solid line) and CBs (dashed line) as a function of disk current (mA) at a 1600 rpm rotation rate. The disk potential was swept at 50 mV s⁻¹.

FIG. 19B is a plot showing the oxygen reduction measured on a rotating disk-ring electrode in oxygen-saturated 0.1 M NaOH solutions for Au TDPs (solid line) and CBs (dashed line) as a function of ring current (mA) at a 1600 rpm rotation rate. The ring potential was constant at 1.26 V vs. RHE.

FIG. 20 is a plot showing the average number of electrons exchanged per oxygen molecule derived from the data shown in FIG. 19.

### DETAILED DESCRIPTION

Gold crystalline nanoparticles are disclosed that can be employed in plasmonic and catalytic applications. Generally, these gold nanoparticles are: (1) prisms having ditetragonal shapes; (2) truncated; (3) bounded by 12 facets, including 8 side facets parallel to the principal axis, two terminating facets located at the top of the prism, and two terminating facets located at the bottom of the prism; and (4) have Miller indices notation of {310}. The {310} facets are multiply stepped and can be considered as the vector sum of one {110} facet and two {100} facets. The gold nanoparticles having these features will be referred hereinafter as “gold (Au) truncated ditetragonal nanoprisms” or “Au TDPs”.

The size of the disclosed Au TDPs is not particularly limited; however, the Au TDPs may have long edge lengths from 40 nm to 100 nm. All individual values and subranges from 40 nm to 100 nm are included herein and disclosed herein; for example, the long edge lengths can be from a lower limit of 40, 45, 50, 55, 60, 70, 72, 75, 80, 85, or 90 nm, to an upper limit of 40, 45, 50, 55, 60, 70, 72, 75, 80, 85, 90, 95, or 100 nm. In one exemplary embodiment, the long edge length of the Au TDP is about 45 nm. In another exemplary embodiment, the edge length of the Au TDP is about 72 nm. In some embodiments, the plurality of Au TDPs are uniform and have same or similar edge length, although in other embodiments, the Au TDPs are not uniform and have substantially different edge lengths. The monodisperse Au TDPs may be single crystals bounded by 12 high-index {310} facets. These NPs can function as nanofacet activators and replicate their specific surface features to other functional materials. This provides a new material design strategy and allows for systematic investigation of how catalysis on high-energy surfaces proceeds.

The disclosed gold crystalline nanoparticle(s) are also used as a facet-specific support for catalytically active metals, such as platinum (Pt) palladium (Pd), ruthenium (Ru), and related alloys of these noble metals. The catalytically active metals on Au TDP support, in turn, can be incorporated in electrodes of electrochemical devices, such as fuel cells, to accelerate electrochemical reactions at electrode surfaces. Specifically, high-indexed surfaces of the Au TDP NPs leave a distinct electrochemical feature when surfactants are removed and can be successfully used as stable, facet-specific supports. The high-index-facet features readily allow for placement of a monolayer of the catalytically active metals and promote their catalytic performance. This approach of activating catalytically active metals is distinct from the core/shell synthesis methods of prior art where surface features are typically not replicated during the shell formation.

In addition, method(s) of synthesizing the gold nanoparticles with high-index facets are disclosed. Specifically, the methods may employ a seeding approach to initiate nanoparticle growth by appropriately combining metallic ions, halide ions, and surfactant adsorbates.

The gold seeds used for synthesis of uniform Au TDP NPs can be prepared by any method known in the art. For example, Au seeds can be prepared by quickly injecting ice-cold sodium borohydrate (NaBH₄) into a rapidly stirred mixture of HAuCl₄ and cetyltrimethylammonium bromide (CTAB). The resulting seeds have the size of about 3 to 5 nm, which is sufficient to grow high-purity Au TDPs.

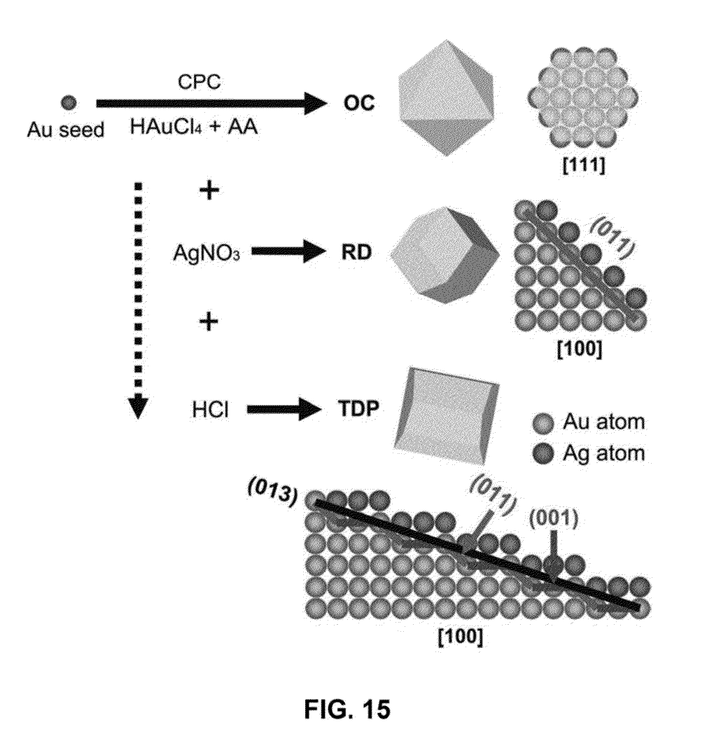

Generally, the seed-mediated method for synthesis of uniform Au TDP NPs, which are bounded by 12 high-index {310} facets, involves (1) injecting Au seeds into a growth solution containing a chloroauric acid (HAuCl₄), silver nitrate (AgNO₃), hydrochloric acid (HCl), ascorbic acid (AA), and cetylpyridinium chloride (CPC) while stirring, and (2) leaving the solution undisturbed until the reaction is completed, which can range between 2 to 48 hours, under suitable temperature and pressure (e.g. ambient). The growth solution can be prepared by consecutively adding HAuCl₄, AgNO₃, HCl, and AA into an aqueous solution of CPC at a molar ratio of about 0.001 (HAuCl₄):0.2 (AgNO₃):100 (HCl):1.4 (AA):200 (CPC). For example into a 10 mL aqueous solution of 0.1 M CPC, 0.5 mL of 0.01 mM HAuCl₄, 0.1 mL of 0.01 M AgNO₃, 0.5 mL of 1.0 M HCl, and 0.07 mL of 0.1 M AA can be added to produce the desired molar ratio. The seed solution is preferably diluted 10-50 times with aqueous solution of CPC (e.g. 0.1 M). A typical synthesis of TDP Au NPs is initiated by the addition of the diluted seeds equivalent to 1 μL of original seed solution, to the growth solution under stirring. FIG. 15 is a schematic illustration that shows the formation mechanism of Au NPs bound by different index facets and the corresponding atomic models of these facets viewed along a three zone axis. In particular, depending on the presence or absence of silver nitrate (AgNO₃) and/or hydrochloric acid (HCl) in the growth solution, three distinct crystalline nanoparticle assemblies can be formed based on the selective face-blocking effect from adsorbates. Without adding both Ag+ and HCl, but keeping all other experimental conditions unchanged, octahedral Au NPs (OC) bound by {111} facets are produced. It is believed that the OC low-energy {111} facets are retained by CPC capping in the thermodynamically controlled reaction. Even when only HCl is added, octahedral Au NPs are still formed, although they are formed relatively slowly due to the decreased reducing power of AA after adding HCl. However, when only Ag+ ions are added, rhombic dodecahedra NPs (RD) bound by {110} facets can be obtained. It is believed that the effect of Ag+ underpotential deposition (UPD) becomes dominant over the surfactant effect from CPC after the Ag+ ions are introduced, due to a relatively low binding affinity of CPC for Au surfaces. Ag+ can be considered as a selective face-blocking adsorbate through the UPD mechanism. The difference in the onset of Ag+ UPD for various crystalline facets of Au leads to the preferable deposition of Ag on the gold surface in the order of {110}> {100}> {111}. Therefore, a Ag monolayer can be formed more favorably on the Au {110} facets. The repeated galvanic reaction of a Ag monolayer by Au ions can significantly retard the total growth of the Au {110} facets. The presence of a Ag monolayer or sub-monolayer on the Au {110} facets acts as a strongly binding surfactant; that results in a slower growth of Au {110} facets. This mechanism becomes dominant in determining the final NP structure.

Thus, the formation of the {310}-facet-bounded truncated ditetragonal prism gold nanoparticles (TDP) can be attributed to the synergistic function of Ag+, halide ions, and the surfactant CPC. It is believed that the cooperative action of Ag+ and HCl promotes the Ag+ UPD on the Au {100} facets and increases the proportion of Au {100} facets in the final structure. Meanwhile, the steps formed by sub-facets provide open sites with a larger UPD shift for Ag deposition and can be stabilized by Ag, resulting in the unique TDP shape.

It is to be understood, however, that those skilled in the art may develop other structural and functional modifications without significantly departing from the scope of the disclosed invention.

### EXAMPLES

### Example 1

This example illustrates the synthesis of gold seeds using the conventional synthesis method of the prior art. Au seeds were prepared by quickly injecting 0.60 mL of ice-cold, freshly prepared NaBH₄ (10 mM; 99.99%; Sigma-Aldrich) into a rapidly stirred mixture of gold (III) chloride trihydrate (HAuCl₄.3H₂O, 99.9+%; Sigma-Aldrich) (0.01M, 0.25 mL) and cetyltrimethylammonium bromide (CTAB; 99.9%; Sigma-Aldrich) (0.1M, 9.75 mL). The seed solution was stirred for 2 minutes and then left undisturbed for 2 hours.

### Example 2

This example illustrates the synthesis of gold ditetragonal prisms using the gold seeds prepared in Example 1. A growth solution was prepared by consecutively adding 0.5 mL of 10 mM HAuCl₄, 0.1 mL of 10 mM silver nitrate (AgNO₃; 99.9999%; Sigma-Aldrich), 0.5 mL of 1.0 M HCl (volumetric solution; Sigma-Aldrich), and then 0.07 mL of 100 mM L-ascorbic acid (AA, 99+%; Sigma-Aldrich) to a 10 mL aqueous solution of 0.1 M cetylpyridinium chloride (CPC, 99%; Sigma-Aldrich). The seed solution was diluted 50 times with 0.1 M CPC. Synthesis of 45-nm Au TDP NPs was initiated by the addition of 50 μL of the diluted seeds, equivalent to 1 μL of original seed solution, to the growth solution under stirring. The growth was then left undisturbed at room temperature until the reaction completed. The synthesized NPs were washed twice using Milli-Q water by centrifugation for further characterizations.

### Example 3

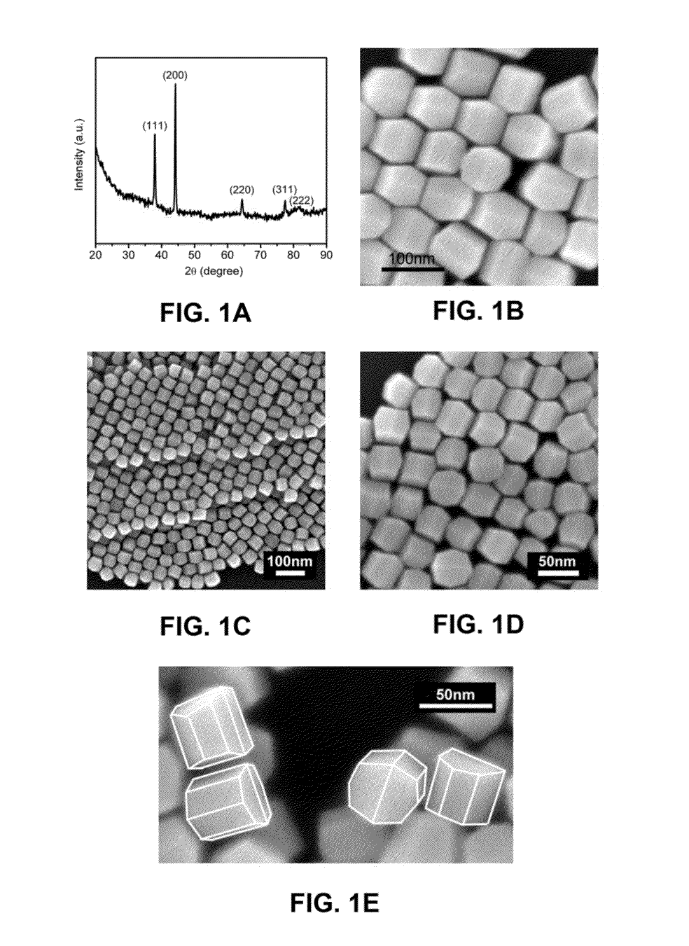

XRD spectra were collected on a Rigaku Miniflex II X-ray diffractometer. SEM and TEM characterizations were conducted on a Hitachi S-4800 Scanning Electron Microscope, a JEOL JEM-2100F high-resolution Analytical Transmission Electron Microscope, and a FEI Titan 80-300 Environmental Transmission Electron Microscope (E-TEM). As illustrated in FIG. 1A, the X-ray powder diffraction (XRD) pattern of the synthesized NPs (Example 2) matches the FCC gold structure (JCPDS 4-0784). FIGS. 1C-1E show scanning electron microscopy (SEM) images of the NPs obtained from a reaction in which 50 μL of the diluted seeds were added, which is an equivalent of 1 μL of the original seed solution. Due to their high monodispersity, the uniform particles can self-assemble into ordered and well-packed structures, as shown in the low magnification SEM image provided in FIG. 1B.

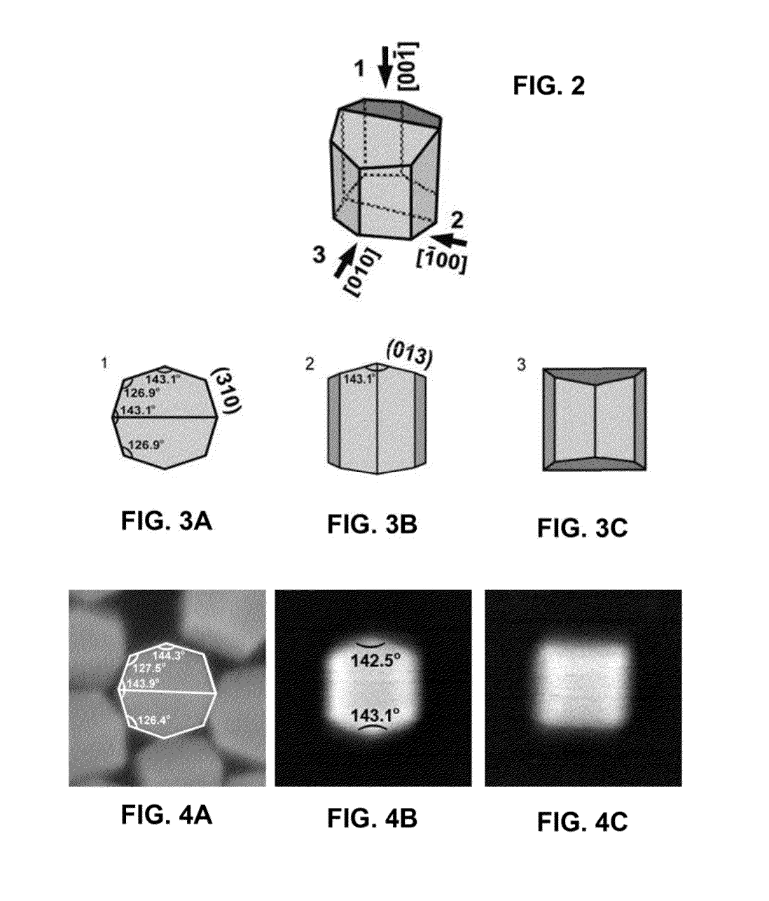

High-magnification observations (FIGS. 1D-1E) reveal well-defined facets with an average long edge length of ˜45 nm. These NPs exhibit a ditetragonal prism shape with truncated ends, and smaller than the ones reported in Trong, et al (˜100-200 nm) (J. Phys. Chem. C. 2011, 115, 3638, which is incorporated in this disclosure by reference in its entirety.) As shown in FIG. 1E, they are bounded by 12 facets, including 8 side facets parallel to the principal axis and two terminating facets located at each of the two ends. FIG. 2 is a schematic illustration of TDP that indicates the projections along three orthogonal viewing directions (FIGS. 3A-3C), which are in agreement with the observed particle profile shown in FIGS. 4A-4C.

The SEM image of FIG. 4A shows that the particles have a ditetragonal cross-section when surrounded by neighboring NPs. The measured inner angles match closely those calculated from an ideal TDP with high-index {310} side facets (FIG. 3A). Similarly, a side-view projection (FIG. 4B) exhibits measured angles between edge-on facets at the two ends of the prism which also agree with expected values for {310} facets (FIG. 3B). These measurements indicate that the synthesized Au NPs have a TDP shape bound by {310} facets.

### Example 4

By varying the volume of seed particles added to the growth solution, the size of the Au TDP NPs, namely the length of the longest edge, can be adjusted. For example, Au TDP NPs with the edge length of ˜72 nm were synthesized by adding an equivalent of 0.25 μL of the non-diluted seed solution, all while maintaining the TDP shape and high yield (>95%) (FIG. 1B).

### Example 5

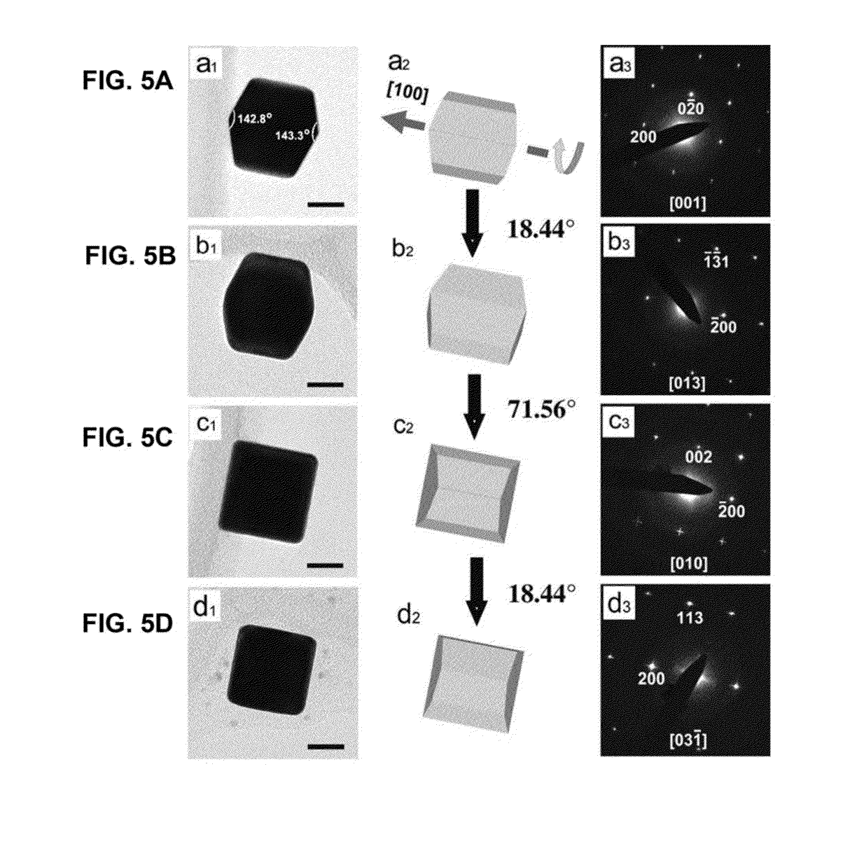

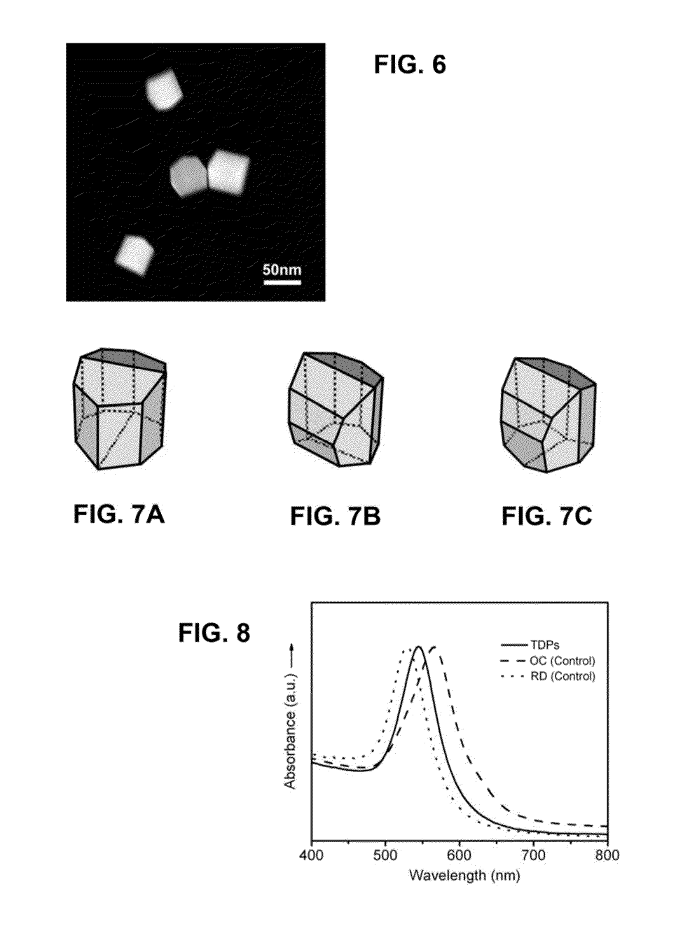

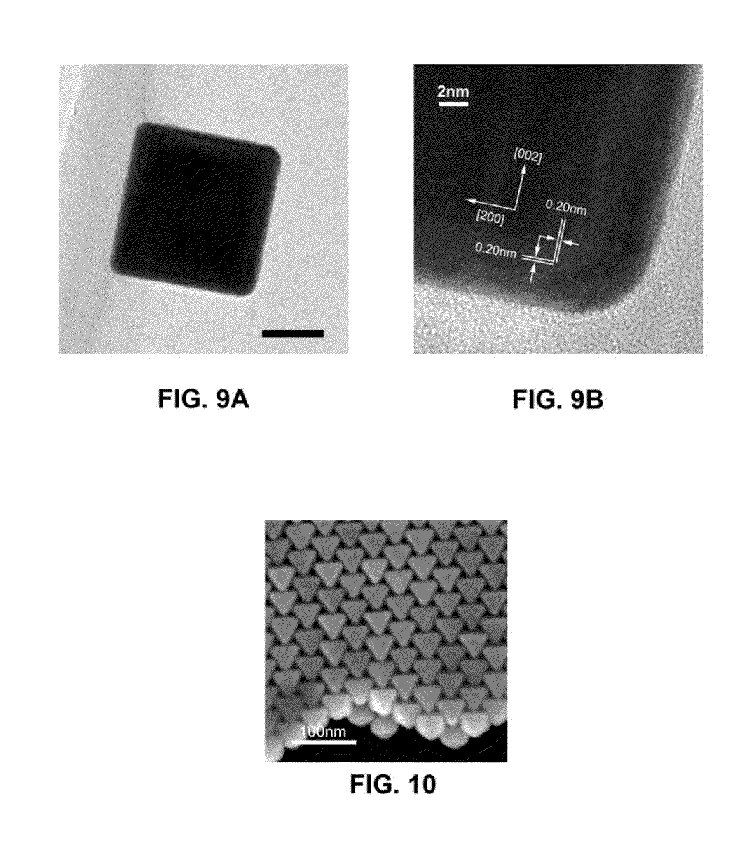

This example illustrates the structural characterization of Au TDPs. The shape and internal structure of Au TDP NPs were investigated using transmission electron microscopy (TEM). FIGS. 5A through 5D present four representative TEM images of the NPs (identified as a₁, b₁, e₁, and d₁). The corresponding selected area electron diffraction (SAED) patterns which demonstrate the NP orientation (FIGS. 5A-5D; a₃, b₃, c₃, and d₃). The measured projected contours of NPs match the profiles of the ideal TDP in corresponding orientations (FIGS. 5A-5D; a₂, b₂, c₂, and d₂). When viewed along the [001] direction, the angle between the two end faces of the TDP is visible and can be used to determine the plane indices of the end faces as {310} (FIG. 5A). The SAED patterns and high-resolution TEM (HRTEM) analysis (FIGS. 5C and 9) confirm that the principal axis that is parallel to the 8 side faces is [100]. All of the side-views can be obtained by rotating a TDP with the 8 {310} side faces around the principal axis [100]. Combined with the SEM analysis, these structural characterizations confirm that the Au NPs are substantially defect-free single-crystalline TDPs bounded by 12 high-index {310} facets. The majority of the Au NPs exhibited the standard TDP shape illustrated in FIG. 2. A minority of NPs showed slight shape differences, but they were still bounded by 12{310} facets (FIG. 6 and FIGS. 7A-7C).

### Example 6

This example illustrates the optical characterization of Au TDPs. UV-vis spectra were collected on a Perkin-Elmer Lambda 35 spectrometer. FIG. 8 is the UV-vis absorption spectrum of the synthesized Au TDP NPs that shows the difference in absorbance between the Au TDP NPs (solid curve), the octahedral (OC) Au NPs (dashed curve), and the rhombic dodecahedral (RD) Au NPs (dotted curve). The spectrum exhibits only one strong surface resonance (SPR) peak at 545 nm. The spectrum features differ from that of the TDP NPs reported in Trong (2011), which shows two broad peaks corresponding to the transverse and longitudinal SPR modes. The difference arises from the more symmetric aspect ratio and narrow size distribution of the Au TDP NPs.

### Example 7

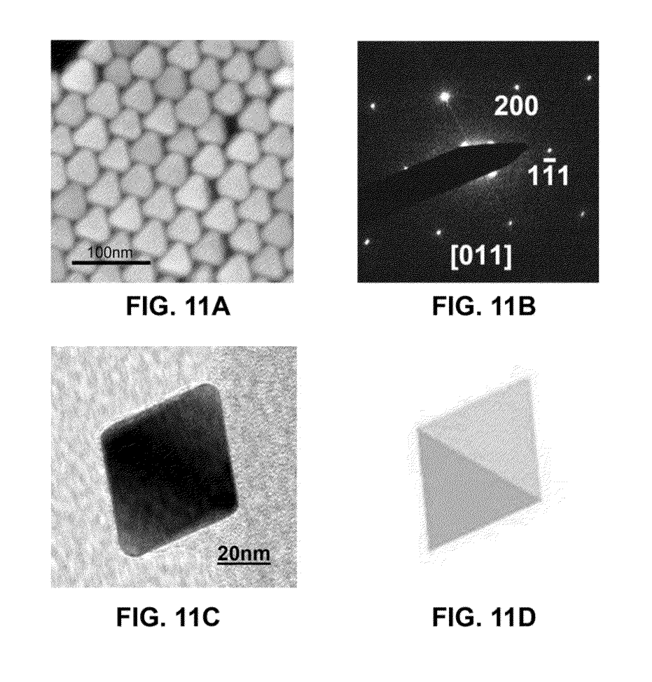

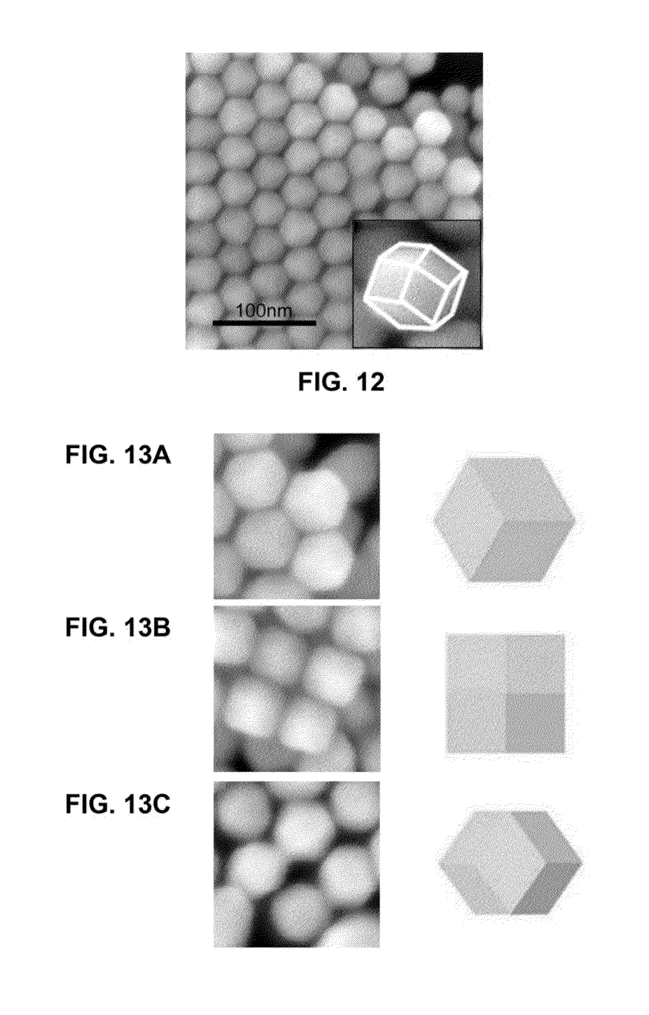

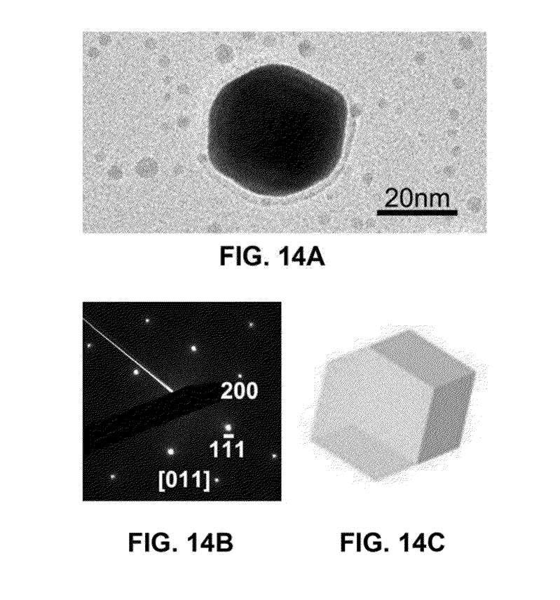

This example provides a comparison of Au TDPs with other structures. Several control experiments were carried out to probe the mechanism of Au TDP NPs formation. Under the growth conditions described in Example 2, which yields a low generation rate of gold atoms, the selective face-blocking effect from adsorbates is found to dominate the growth kinetics (Niu et al., 2009). Without adding both Ag+ and HCl, but keeping all other experimental conditions unchanged, octahedral Au NPs bound by {111} facets were synthesized (FIG. 10), suggesting that the low-energy {111} facets are retained by CPC capping in the thermodynamically controlled reaction. Even when only HCl was added, octahedral Au NPs were still formed relatively slowly due to the decreased reducing power of AA after adding HCl (FIG. 11). However, when only Ag+ was added, rhombic dodecahedra NPs bound by {110} facets were obtained (FIG. 12 and FIG. 13). This indicates that the effect of Ag underpotential deposition (UPD) becomes dominant over the surfactant effect from CPC after introducing Ag+, due to a relatively low binding affinity of CPC for Au surfaces. Ag+ is considered as a selective face-blocking adsorbate through the UPD mechanism and it has been used by Liu, et al. in other solution-based syntheses to stabilize high-index facets. (J. Phys. Chem. B. 2005, 109, 22192, which is incorporated in this disclosure by reference in its entirety.)

The difference in the onset of Ag+ UPD for various crystalline facets of Au leads to the preferable deposition of Ag on a Au surface in the order of {110}> {100}>{111}. Therefore, a Ag monolayer can be formed more favorably on the Au {110} facets. The repeated galvanic reaction of a Ag monolayer by Au ions significantly retards the total growth of the Au {110} facets. The presence of a Ag monolayer or sub-monolayer on the Au {110} facets acts as a strongly binding surfactant that results in a slower growth of Au {110} facets, which becomes a dominant force in determining the final NP structure formation.

By adding both Ag+ and HCl, TDP NPs bounded by 12 {310} facets were synthesized. It is believed that the cooperative action of Ag+ and HCl promotes the Ag+ UPD on the Au {100} facets and increases the proportion of Au {100} facets in the final structure. Meanwhile, the steps formed by sub-facets provide open sites with a larger UPD shift for Ag deposition and were stabilized by Ag, resulting in the unique TDP shape.

Such synergetic role of Ag+ and HCl was also indicated in the seed-mediated synthesis reported in Millstone (2008), Personick (2011), Ming, et al. (J. Am. Chem. Soc. 2009, 131, 16350), Zhang, et al. (J. Am. Chem. Soc. 2010, 132, 14012), and Zheng, et al. (Small 2011, 7, 2307), each of which is incorporated in this disclosure by reference in its entirety. In these studies, different surfactants (e.g. CTAB, cetyltrimethylammonium chloride (CTAC), or CPC) were used and combining Ag+ and HCl led to the formation of Au tetrahexahedra (THH) NPs bound by 24 {730} facets (the vector sum of 3 {110} facets and 4 {100} facets) and concave cubic NPs bound by 24 {720} facets (the vector sum of 2 {110} facets and 5 {100} facets). These results indicate that the type of surfactant also has an effect on the proportion of {110} and {100} sub-facets present in the high-index facets.

### Example 8

This example describes the manufacture of thin-film electrodes with Au TDP NPs and the formation of thin-film electrodes of Au TDPs coated with an atomically thin layer of Pt. The electrodes were manufactured by placing an aliquot of the aqueous Au TDP NP suspension onto polished glassy carbon rotating disk electrodes (5 mm diameter, Pine Instrument). After drying in air, the electrodes were washed twice with ethanol before electrochemical measurements of the resulting Au TDP thin film electrodes. Thin film electrodes of Au TDP coated with an atomically thin layer of Pt were made by exposing Au TDP NP thin-film electrodes to galvanic replacement of an underpotentially deposited Cu monolayer following the methods of Wang, et a. J Am. Chem. Soc. 2009, 131, 17298, which is incorporated in this disclosure by reference in its entirety. The Cu monolayer deposition was carried out in a 1 mM CuSO₄, 0.05 M H₂SO₄ solution, and galvanic replacement of Cu by Pt took place in a 1 mM K₂PtCl₄, 0.05 M H₂SO₄ solution, resulting in thin-film electrodes of Au TDPs coated with an atomically thin layer of Pt.

### Example 9

This example describes electrochemical characterization of Au TDPs. Cyclic voltammetry and hydrogen evolution/oxidation reaction polarization curves were measured in a three-electrode cell with a Volta PGZ402 potentiostat at room temperature. A leak-free (Ag/AgCl, 3M NaCl) electrode served as the reference electrode, and a Pt flag was employed as the counter electrode. The potentials are reported with respect to a reversible hydrogen electrode (RHE).

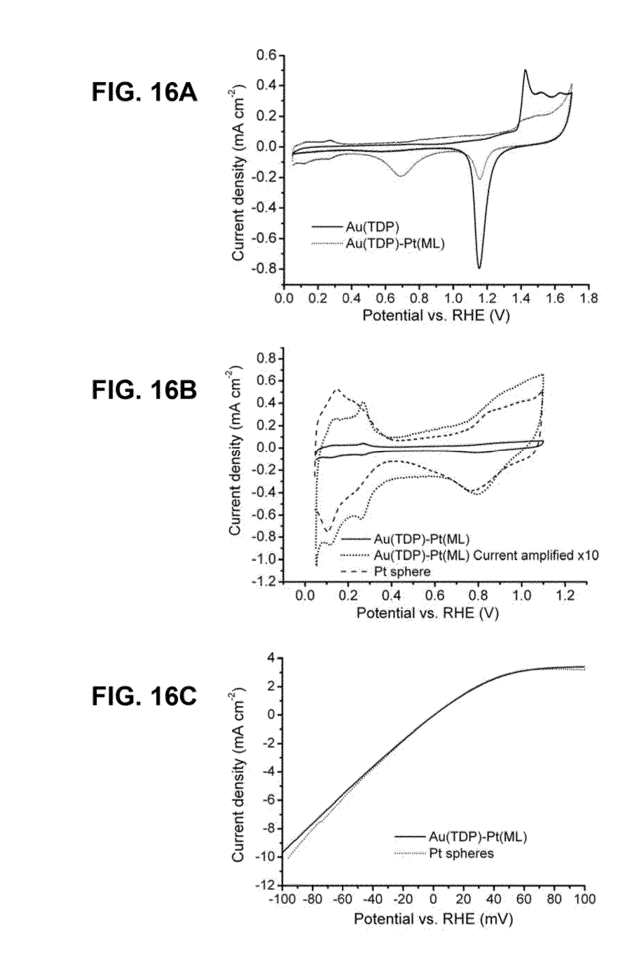

The surface structure of the Au TDP NPs was confirmed by electrochemical measurements. Au surface oxidation at potentials above the 1.2 V curve is facet-sensitive. While a single large current peak occurs during cyclic voltammetry (CV) on close-packed Au {111} facets, multiple small peaks (not-separated) characterize more open structures, such as {100}, {110}, and higher indexed facets. FIG. 16A shows cyclic voltammetry (CV) curves for Au TDPs (solid line) and Au TDPs coated with an atomically thin layer of Pt (dotted line). The data was taken in deaerated 0.1 M H₂SO₄ solutions at a rate of 50 mV s⁻¹. (The current densities were normalized by the geometric area of the 0.5 cm-diameter electrode surface.) The CV curve for the Au TDP NPs (solid) in FIG. 16A exhibits three clear and small peaks (at voltages above 1.2V), which is consistent with its well-defined high-index facets. Such distinct electrochemical surface features from Au TDP nanofacets confirm their high surface purity. This result also verifies that the surfactants (CPC) have been removed from the Au TDP NPs surfaces by ethanol-washing, and that the high-index facets remain intact.

### Example 10

The clean and stable crystalline profile of the Au TDP NPs was further examined as a facet-specific support for catalytically active metals, specifically platinum (Pt). A Pt monolayer (ML) was placed on the surface of the Au TDP NPs by galvanic replacement of an underpotentially deposited Cu monolayer. The formation of complete Pt monolayer, bilayer and multilayer shells on <10-nm Pd nanoparticles using Z-contrast STEM and elementary-sensitive EELS was demonstrated by Wang, et a. J. Am. Chem. Soc. 2009, 131, 17298, which is incorporated in this disclosure by reference in its entirety. The Cu monolayer deposition was carried out in a 1 mM CuSO₄, 0.05 M H₂SO₄ solution, and galvanic replacement of Cu by Pt took place in a 1 mM K₂PtCl₄, 0.05 M H₂SO₄ solution. The lack of Z-contrast between Pt and Au and the large core-to-shell thickness ratio made the direct imaging of Pt layer difficult in that study. Nevertheless, the described electrochemical behaviors suggest that a structure of the deposited Pt is a monolayer with facets matching to the underlying Au crystalline structure. Indeed, a smaller Au reduction peak at 1.15 V and an additional reduction peak at 0.7 V in FIG. 16A for the Au(TDP)-Pt(ML) sample (dotted line) are consistent with the presence of a Pt monolayer. This Pt monolayer partly shifts the reduction of surface oxide below 0.9 V, as commonly seen on Pt surfaces.

FIG. 16B shows CV curves for Au TDPs (solid and dotted lines) and Pt spheres (dashed line). The data was taken in deaerated 0.1 M H₂SO₄ solutions at a rate of 50 mV s⁻¹. For the Au(TDP)-Pt(ML) sample, the hydrogen desorption peak at 0.3 V is higher than that at 0.15 V (FIG. 16B), distinctly differing from the ratio of the two peaks in the CV curve for sphere-like Pt NPs (45% Pt/C were purchased from E-TEK), as shown by the dashed curve in FIG. 16B.

This feature suggests that Pt monolayer lattice is not hexagonal close-packed ({111}), but mimics the underlying surface features of Au NPs containing rich {100} sub-facets. From the integrated hydrogen desorption charges, the ratio between electrochemical surface areas of the Au(TDP)-Pt(ML) and the Pt NPs samples is estimated to be 1:20. This is largely because the Pt NPs are much smaller (average diameter about 2.5 nm), and thus, have much higher Pt surface area.

FIG. 16C shows polarization curves in hydrogen-saturated 0.1 M H₂SO₄ solutions taken at 5 mV s⁻¹ and a 2500 rpm rotation rate for Au TDPs (solid line) and Pt spheres (dotted line). The polarization curves for hydrogen evolution and oxidation reactions are similar, which suggests that the Pt monolayer on the high-index facets is much more active per Pt surface area than the close-packed surface of spherical Pt NPs. Accordingly, Au TDPs serve as nanofacet-activating substrates by translating their high-index-facet features to the supported materials, which results in a high electrochemical catalysis activity of the added Pt monolayer. The results illustrate a feasible way to study facet-dependent catalytic behavior of reactive metals using well-shaped Au NPs as facet-specific supports, as well as creating new opportunities for an enhancement of catalytic properties by changing the surface features of the support.

### Example 11

This example illustrates the role of Au TDPs as active catalysts for oxygen reduction reaction (ORR) in alkaline solutions. Au TDP performance was distinctly different from Au cube (CB) and OC nanoparticles. While Au OCs were obtained in the CPC solution by reduction of HAuCl₄ with ascorbic-acid at 25° C., introducing KBr and initiating growth at 32° C. based on the same protocol yielded Au CBs bound by {100} facets (see FIG. 17).

Previous studies on single crystal electrodes showed that oxygen (O₂) reduction on Au(111) surface is incomplete, forming hydrogen peroxide (H₂O₂) as the product, while the Au(100) surface supports a complete four-electron (4e) oxygen reduction to water (2H₂O) over a narrow potential region. Au OC with the {111} facets and Au CB with the {100} facets behave similarly as their corresponding single crystal surfaces. As shown in FIG. 18, while the ORR current on the OCs levels off at −3 mA cm⁻², the current on the CBs exceeds that level in a narrow potential range. More importantly, the ORR current on the TDPs is the largest below 0.6 V.

The current leveling off at −3 mA cm² is believed to be due to the mass transport limitation for 2e ORR with H₂O₂ as the product. Rotating ring-disk electrode measurements directly can detect the amount of H₂O₂ generated on the disk by measuring the H₂O₂ oxidation current on a Pt ring electrode. FIG. 19A shows the ORR polarization curves on the disk electrode while FIG. 19B plots the corresponding ring currents. For the CBs, when the disk current decreases after reaching the maximum around 0.65 V in the negative potential sweep, the ring current rises, confirming that 2e ORR occurred. The behavior differs on the TDPs. The H₂O₂ was detected on the ring over wider potential region, but the current was lower than that on CBs at lower potentials. From these data, the average number of electron transfer per oxygen was obtained (see FIG. 20), which shows a value above 3.8 over the whole potential region on the TDP. This has not heretofore been known to be observed on any Au single crystal surfaces in previous studies.

All publications and patents mentioned in this specification are incorporated by reference in their entireties in this disclosure. Various modifications and variations of the described nanomaterials and methods will be apparent to those skilled in the art without departing from the scope and spirit of the invention. Although the disclosure has been described in connection with specific preferred embodiments, it should be understood that the invention as claimed should not be unduly limited to such specific embodiments. Indeed, those skilled in the art will recognize, or be able to ascertain using the teaching of this disclosure and no more than routine experimentation, many equivalents to the specific embodiments of the disclosed invention described. Such equivalents are intended to be encompassed by the following claims.

1. A crystalline nanomaterial, comprising:
a truncated ditetragonal gold prism.

2. The crystalline nanomaterial of claim 1, wherein the truncated ditetragonal gold prism has a face-centered cubic crystal structure bounded by 12 high-index {310} facets.

3. The crystalline nanomaterial of claim 1, wherein the truncated ditetragonal gold prism comprises 8 side facets parallel to a principal axis, two terminating facets located at the top of the truncated ditetragonal gold prism, and two terminating facets located at the bottom of the truncated ditetragonal gold prism.

4. The crystalline nanomaterial of claim 2, wherein the {310} facets are a vector sum of one {110} facet and two {100} facets.

5. The crystalline nanomaterial of claim 1, further comprising an atomically thin coating of catalytically active metal.

6. The crystalline nanomaterial of claim 5, wherein the atomically thin coating of catalytically active metal at least partially encapsulates the truncated ditetragonal gold prism.

7. The crystalline nanomaterial of claim 5, wherein the catalytically active metal is platinum.

8. The crystalline nanomaterial of claim 7, wherein the atomically thin coating of platinum reproduces the surface features of the truncated ditetragonal gold prism.

9. The crystalline nanomaterial of claim 8, wherein the atomically thin coating of platinum reproduces the high-index facets of the truncated ditetragonal gold prism.

10. The crystalline nanomaterial of claim 1, wherein the truncated ditetragonal gold prism has an average long edge length of between 40 nm and 100 nm.

11. The crystalline nanomaterial of claim 10, wherein an average long edge length of the truncated ditetragonal gold prism is about 45 nm or about 72.

12. A method of synthesizing a truncated ditetragonal gold nanoprism, comprising:
synthesizing one or more gold seeds of crystalline gold;
injecting gold seeds into a growth solution while stirring;
leaving the growth solution undisturbed for 2 to 48 hours under suitable temperature and pressure conditions; and
isolating one or more truncated ditetragonal gold nanoprisms,
wherein the growth solution comprises a metallic ion, a halide ion, and a surfactant adsorbate.

13. The method of claim 12, wherein the metallic ion is a silver ion (Ag⁺).

14. The method of claim 13, wherein the silver ion (Ag⁺) is derived from a silver nitrate (AgNO₃).

15. The method of claim 12, wherein the halide ion is a chloride ion (Cl⁻).

16. The method of claim 15, wherein the chloride ion (Cl⁻) is derived from a hydrochloric acid (HCl).

17. The method of claim 12, wherein the surfactant adsorbate is cetylpyridinium chloride (CPC).

18. The method of claim 12, wherein the growth solution further comprises a source of gold ions and ascorbic acid.

19. The method of claim 12, wherein the growth solution is prepared by consecutively adding to an aqueous solution of CPC: HAuCl₄, AgNO₃, HCl, and AA at a molar ratio of about 0.001 (HAuCl₄):0.2 (AgNO₃):100 (HCl):1.4 (AA):200 (CPC).

20. The method of claim 19, wherein the growth solution is prepared by consecutively adding to a 10 mL aqueous solution of 0.1M cetylpyridinium chloride (CPC) 0.5 mL of 10 mM HAuCl₄, 0.1 mL of 10 mM AgNO₃, 0.5 mL of 1.0M HCl, and then 0.07 mL of 100 mM L-ascorbic acid.

21. The method of claim 12, wherein:
the synthesizing one or more gold seeds of crystalline gold comprises injecting ice-cold sodium borohydride (NaBH₄) into a rapidly stirred mixture of chloroauric acid (HAuCl₄) and cetyltrimethylammonium bromide (CTAB);
stirring the mixture for 1 to 5 minutes; and
allowing the gold seeds to form for 30 to 180 minutes.

22. The method of claim 21, wherein the synthesized seeds are diluted 10-50 times with aqueous solution of CPC.

23. A catalyst comprising:
a truncated ditetragonal gold nanoprism support having a face-centered cubic crystal structure bounded by 12 high-index {310} facets; and
an atomically thin layer of catalytically active metal that at least partially encapsulates the truncated ditetragonal gold nanoprism support.

24. The catalyst of claim 23, wherein the atomically thin layer comprises 1 to 12 facets covered by the catalytically active metal.

25. The catalyst of claim 23, wherein the catalytically active metal is platinum (Pt), palladium (Pd), ruthenium (Ru), or a combination thereof.

26. The catalyst of claim 23, wherein truncated ditetragonal gold nanoprism support enhances the activity of the catalytically active metal above the rate of activity for the catalytically active metal alone.

27. The catalyst of claim 23, wherein the atomically thin coating of catalytically active metal reproduces surface features of the truncated ditetragonal gold nanoprism support.

28. An electrode comprising:
a truncated ditetragonal gold nanoprism support having a face-centered cubic crystal structure bounded by 12 high-index {310} facets; and
an atomically thin coating of catalytically active metal that at least partially encapsulates the truncated ditetragonal gold nanoprism support.

29. The electrode of claim 28, wherein the catalytically active metal is platinum (Pt).

30. An energy conversion device comprising:
a first electrode;
a conducting electrolyte; and
a second electrode,
wherein at least one of the first or second electrodes comprises a plurality of the catalyst of claim 23.

31. A composition, comprising
a plurality of monodisperse truncated ditetragonal gold prisms.

32. The composition of claim 31, wherein the truncated ditetragonal gold prisms have a face-centered cubic crystal structure bounded by 12 high-index {310} facets.

33. An active oxygen reduction catalyst in alkaline solutions comprising:
a truncated ditetragonal gold nanoprism having a face-centered cubic crystal structure bounded by 12 high-index {310} facets.
